(19) United States
(12) Patent Application Publication
(10) Pub. No.: US 2021/0328077 A1
(43) Pub. Date: Oct. 21, 2021

(54) Merged PiN Schottky (MPS) Diode With Multiple Cell Designs And Manufacturing Method Thereof

(71) Applicants: Xiaotian Yu, LOS ANGELES, CA (US); Zheng Zuo, LOS ANGELES, CA (US); Ruigang Li, LOS ANGELES, CA (US)

(72) Inventors: Xiaotian Yu, LOS ANGELES, CA (US); Zheng Zuo, LOS ANGELES, CA (US); Ruigang Li, LOS ANGELES, CA (US)

(73) Assignee: AZ Power, Inc, CULVER CITY, CA (US)

(21) Appl. No.: 17/235,891

(22) Filed: Apr. 20, 2021

Related U.S. Application Data
(60) Provisional application No. 63/012,893, filed on Apr. 20, 2020.

(51) Int. Cl. H01L 29/872; H01L 29/16; H01L 29/06; H01L 29/45; H01L 29/47; H01L 21/04; H01L 29/66

(52) U.S. Cl. CPC H01L 29/872; H01L 29/1608; H01L 29/0692; H01L 29/45; H01L 29/6606; H01L 21/0465; H01L 21/0485; H01L 21/0495; H01L 29/47

(57) ABSTRACT

A semiconductor device may include a substrate having a first conductivity type; an epitaxial layer having the first conductivity type deposited on one side of the substrate; a plurality of regions having a second conductivity type formed under a top surface of the epitaxial layer; a first Ohmic metal patterned and deposited on top of the regions with the second conductivity type; a Schottky contact metal deposited on top of the entire epitaxial layer to form a Schottky junction; and a second Ohmic metal deposited on a backside of the substrate, wherein the regions include one or more wide regions, each having different widths that can be optimized to simultaneously obtain high surge current capability and preserve a low forward voltage drop and reverse leakage current.

### CROSS-REFERENCE TO RELATED APPLICATIONS

This application claims priority under 35 U.S.C. § 119 (e) to U.S. Provisional Patent Application Ser. No. 63/012,893, filed on Apr. 20, 2020, the entire contents of which are hereby incorporated by reference.

### FIELD OF THE INVENTION

The present invention relates to a power diode structure, and more particularly to a merged PiN junction Schottky (MPS) diode with enhanced reliability under a surge current.

### BACKGROUND OF THE INVENTION

Power devices include power diodes and power switching transistors. Power diodes have two modes of operation in circuit applications, which are conduction mode and blocking mode. For the conduction mode, in addition to nominal current conditions, there is an occasional surge current condition. Under the abnormal conditions with surge current, the diode may have instant energy overshoot and chip temperature rise, resulting in device failure.

Power devices are expected to endure high current stresses under surges caused by circuit failure or lightening. Usually a great amount of energy, caused by high current multiplied by high voltage drop, flows into the device in quite a short time, leading to rapidly raised temperature and possibly a device failure. Surge capability is a key performance index which describes the robustness of power devices under extreme operating conditions. Devices with preeminent surge capability can dissipate such energy efficiently without a failure, thus offering a higher safety margin to the power system.

Silicon carbide semiconductor has two times larger bandgap compared with Silicon semiconductor. With a higher critical electric field, higher thermal conductivity, lower intrinsic carrier concentration, and higher saturation drift velocity, silicon carbide semiconductor has become an ideal candidate for high voltage, high temperature and high-power devices.

There are two technical routes for commercial devices based on silicon carbide power diodes, namely junction barrier Schottky (JBS) diode structure and merged PiN Schottky (MPS) diode structure.

For silicon carbide (SiC) materials, the Junction Barrier Schottky (JBS) diode is widely used. Armed with excellent characteristics of SiC material and characterized by alternatively arranged small P+ regions in N-drift layer, it has received large attention for its low forward voltage drop and low reverse leakage current. Merged PiN Schottky (MPS) diode was proposed based on the JBS diode structure, with merged large P+ regions into the active region. PN junctions formed by these large P+ regions will turn on under high current flows. Large amount of minority carriers will be injected into the drift layer, providing a lower resistivity and a higher current conduction capability. Thus, it offers higher surge capability compared to traditional JBS diode, as well as preserving a low forward voltage drop and reverse leakage current at the same time.

### SUMMARY OF THE INVENTION

In one aspect, a merged PiN Schottky (MPS) diode may include a silicon carbide substrate having a first conductivity type, an epitaxial layer with the first conductivity type formed on the substrate, In one embodiment, the doping concentration in the epitaxial layer is lower than that in the substrate. The merged PiN Schottky (MPS) diode may further include a plurality of regions having a second conductivity type different from the first conductivity type, and formed under a top surface of the epitaxial layer.

A first Ohmic contact metal is formed on top of each of the regions of the second conductivity type, and a Schottky contact metal is placed on top of the entire epitaxial layer to form a Schottky junction. A second Ohmic contact is formed by a cathode electrode on the back side of the substrate.

In one embodiment, the first conductivity is N type, and the second conductivity type is P type. It is noted that in the merged PiN Schottky (MPS) diode structure, a PN junction can be formed by a P+ region, and a N-type drift region can be turned on under surge current condition, forming a parallel operation mode between the PN junction and the Schottky junction, providing device with better surge current capability.

In a merged PiN Schottky (MPS) diode, the PN junction formed by the P+ region and the N-type drift region can be turned on under surge current condition, forming a parallel operation mode between the PN junction and the Schottky junction, providing device with better surge current capability. The shape, size and arrangement of the P+ region largely affect the electrical characteristics of the merged PiN Schottky (MPS) diode in the event of a high current surge. Therefore, it is important to study the relationship between the structure parameter design of the P+ region and the device surge current capability. With the reasonable design of the width and spacing of P+ region, the turn-on voltage of the PN junction can be reduced, resulting in the lower power loss and temperature rise under the current surge, therefore improving the device surge current capability.

The design of the P+ region not only affects the surge current capability of the device, but also affects the forward voltage drop of the device under the nominal current operation, thereby influencing the conducting performance of the device. Under a nominal current condition, in which current is less than the value of the maximum steady-state operating current given in the product data sheet, because the Schottky barrier height is much lower than the PN junction built-in potential, only the Schottky junction is turned on. If the P+ region is designed with larger size and takes up too much active area, the remaining Schottky junction area will be reduced, the forward voltage drop under the nominal current conduction will increase, resulting in less competitive conducting performance. On the other hand, when the device is subjected to an abnormal surge current shock, the wider P+ region (larger P+ region area) can lower the turn-on voltage of the PN junction. Once the PN junction begins to conduct current, a large amount of minority carriers will be injected into the drift layer to reduce the electrical resistance and device voltage drop. As a result, the capability of device withstanding surge current can be enhanced.

The present invention proceeds from the method of device structure design, aiming to find the optimal solution between the normal current conduction performance and the surge current capability of merged PiN Schottky (MPS) diode.

In another aspect, a method for manufacturing a merged PiN Schottky (MPS) diode may include steps of providing a substrate having a first conductivity type; forming an epitaxial layer with the first conductivity type on top of the substrate; forming a plurality of regions with a second conductivity type under a top surface of the epitaxial layer; forming a plasma spreading layer in each region; depositing and patterning an Ohmic contact metal on the regions with the second conductivity type; depositing a Schottky contact metal on top of the entire epitaxial layer; and forming an Ohmic contact metal on a backside of the substrate.

In one embodiment, the epitaxial layer is made of N-type silicon carbide. In another embodiment, the step of forming a plurality of regions with a second conductivity type under a top surface of the epitaxial layer may include steps of depositing and patterning a mask layer on the epitaxial layer, implanting P-type dopant into the epitaxial layer, and removing the mask layer. It is noted that the dopant can be aluminum or boron.

In a further embodiment, the step of depositing and patterning an Ohmic contact metal on the regions may include a step of annealing the Ohmic metal to enable the metal to be in direct contact with the epitaxial layer. In still a further embodiment, the step of depositing a Schottky contact metal on top of the entire epitaxial layer may include a step of conducting a low temperature annealing of the Schottky contact metal.

### BRIEF DESCRIPTION OF THE DRAWINGS

FIG. 1 is a cross-section view of the merged PiN Schottky (MPS) diode in the present invention.

FIG. 2 is a schematic view of a first layout design of a merged PiN Schottky (MPS) diode with circle cells.

FIG. 3 is a cross-section view of the merged PiN Schottky (MPS) diode in FIG. 2 along line AA′.

FIG. 4 is a partial enlarged cross-section view of the merged PiN Schottky (MPS) diode in FIG. 3.

FIG. 5 is a schematic view of a second layout design of a merged PiN Schottky (MPS) diode.

FIG. 6 is a schematic view of a first alternative of the second layout design of the merged PiN Schottky (MPS) diode shown in FIG. 5.

FIG. 7 is a schematic view of a second alternative of the second layout design of the merged PiN Schottky (MPS) diode shown in FIG. 5.

FIG. 8 is a schematic view of a third alternative of the second layout design of the merged PiN Schottky (MPS) diode shown in FIG. 5.

FIG. 9 is a cross-section view of the merged PiN Schottky (MPS) diode shown in FIG. 8 along line DD′.

FIG. 10 is a schematic view of a third layout design of a merged PiN Schottky (MPS) diode.

FIG. 11. shows a cross-section view of the merged PiN Schottky (MPS) diode shown in FIG. 10 along line EE′.

FIG. 12. is a schematic view of a first alternative of the second layout design of the merged PiN Schottky (MPS) diode shown in FIG. 10.

FIG. 13. is a schematic view of a second alternative of the second layout design of the merged PiN Schottky (MPS) diode shown in FIG. 10.

FIG. 14. is a schematic view of a third alternative of the second layout design of the merged PiN Schottky (MPS) diode shown in FIG. 10.

FIG. 15. is a schematic view of a fourth alternative of the second layout design of the merged PiN Schottky (MPS) diode shown in FIG. 10.

FIG. 16 shows a cross-section view of the merged PiN Schottky (MPS) diode shown in FIG. 15 along line FF′.

FIGS. 17A to 17G illustrate flow diagrams of the method for manufacturing a merged PiN Schottky (MPS) diode in the present invention.

FIG. 18 is a block diagram illustrating the method for manufacturing a merged PiN Schottky (MPS) diode in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

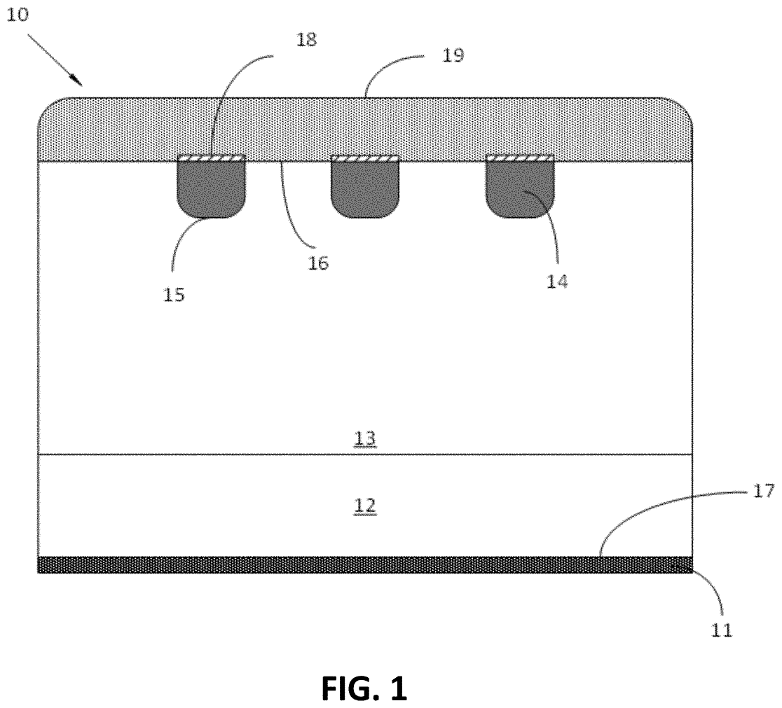

In one aspect as shown in FIG. 1, a merged PiN Schottky (MPS) diode 10 may include a silicon carbide substrate 12 having a first conductivity type, an epitaxial layer 13 with the first conductivity type formed on the substrate 12. In one embodiment, the doping concentration in the epitaxial layer 13 is lower than that in the substrate 12. The merged PiN Schottky (MPS) diode 10 may further include a plurality of regions 14 having a second conductivity type different from the first conductivity type, and formed on the surface of the epitaxial layer 13.

A first Ohmic contact metal 18 is formed on top of each of the regions of the second conductivity type, and a Schottky contact metal 19 is placed on top of the entire epitaxial layer 13 to form a Schottky junction 16. A second Ohmic contact 17 is formed by a cathode electrode 11 on the back side of the substrate 12.

In one embodiment, the first conductivity is N type, and the second conductivity type is P type. It is noted that in the merged PiN Schottky (MPS) diode structure, a PN junction can be formed by a P+ region 14, and a N-type drift region 15 can be turned on under surge current condition, forming a parallel operation mode between the PN junction and the Schottky junction 16, providing device with better surge current capability.

It is noted that the layout design of the merged PiN Schottky (MPS) diode 10 can be strip cell structure, circle cell structure or polygon cell structure. The one-dimensional strip structure has the drawback that the P+ region occupies too much active area, resulting in insufficient Schottky area for normal current operation, leading to a large forward voltage drop of the device. However, two-dimensional circles will also leads to a large P+ percentage because circular cells cannot form a close-packed layout. Therefore, compared with regular polygon cell structure, the device will also have larger forward voltage drop due to inadequate Schottky area under normal current operation.

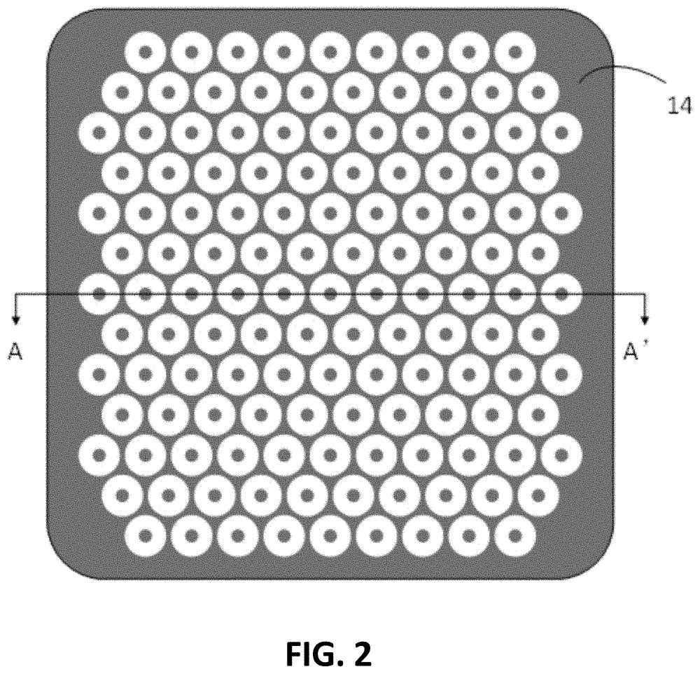

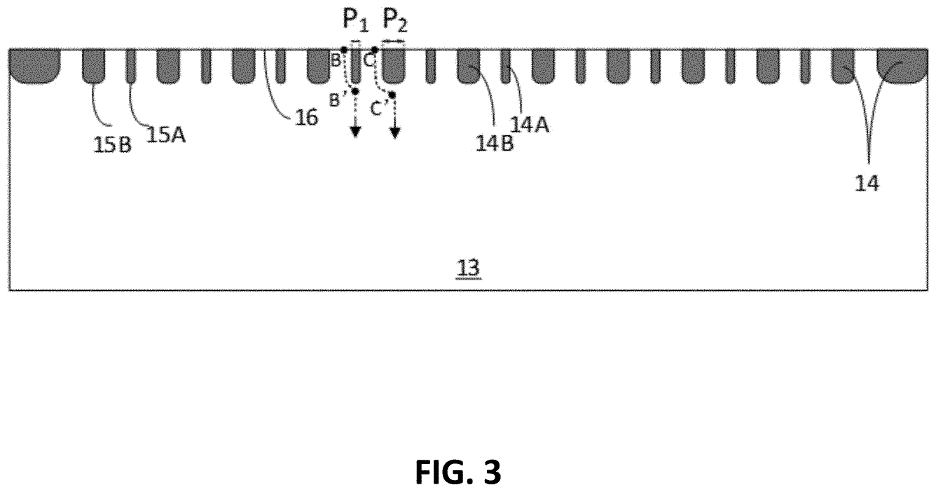

FIG. 2 shows a layout design of a first embodiment, while FIG. 3 is a cross-sectional schematic view of the device structure of the first embodiment along line AA′. As shown in FIG. 3, the width of the regions 14 having the second conductivity type are not uniform, which are denoted as P₁ and P₂, respectively.

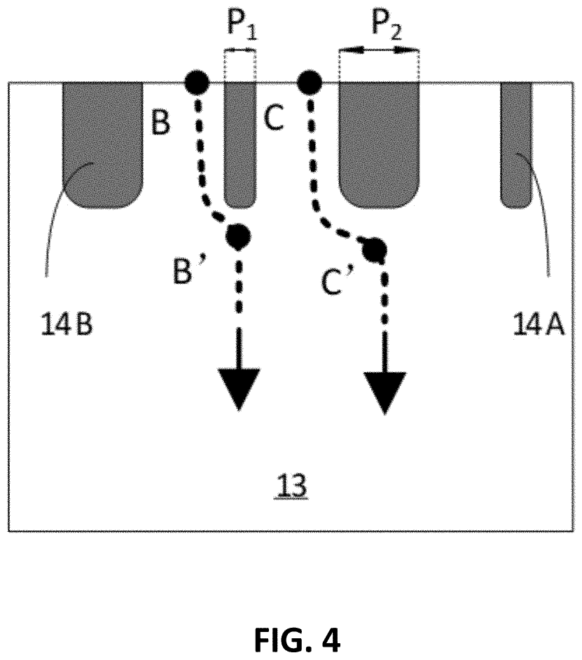

When the MPS diode is under forward bias, the current flows from the anode of the diode through the Schottky junction 16 into the drift region 15, then through the substrate layer 12 and flows out of the cathode electrode 11. Before the current enters the drift region 15, it first passes through the channel region formed between the second conductivity type regions. Meanwhile, the current will form a potential difference on the PN junction, which is formed between the region 14 with second conductivity type and the drift region 15 with first conductivity type. When this potential difference exceeds the built-in potential of the PN junction, the PN junction will be turned on. Changing the width of the second conductivity type region 14 will affect the threshold that triggers the turn-on of the PN junction. Once the PN junction is turned on, the voltage drop between the anode and cathode 11 of the diode is referred to as the PN junction turn-on voltage. The larger the width of the region of the second conductivity type 14, the lower the PN junction turn-on voltage. This is because, as shown in FIG. 4, the dash lines BB′, CC′ respectively show the current paths near the second conductivity type regions with widths P₁ and P₂, respectively. When the potential difference between BB′ and CC′ reaches the built-in potential of the PN junction, the PN junction will be turned on. Here, the potential difference between BB′ and CC′ is equal to the channel current times the resistance along the line BB′ and CC′, separately.

It can be clearly seen from FIG. 4 that when the P+ region spacing is constant, the resistance of the channel is mainly affected by the width of the P+ region 14. If the width of the P+ region is larger (P₂ is greater than P₁), the resistance is larger (R_{CC′} is larger than R_{BB′}). Therefore, once the current increases to the threshold 12 that triggers the first PN junction as shown in 15B in FIG. 3 (formed by the P+ region with the width P₂), the potential difference between CC′ will reach the built-in potential of the PN junction, and the PN junction will be first turned on. As the current continues increasing, once beyond the threshold Ii at which the second PN junction is turned on, the potential difference between BB′ also reaches the built-in potential of the PN junction as shown in 15A in FIG. 3, formed by the P+ region of width P₁.

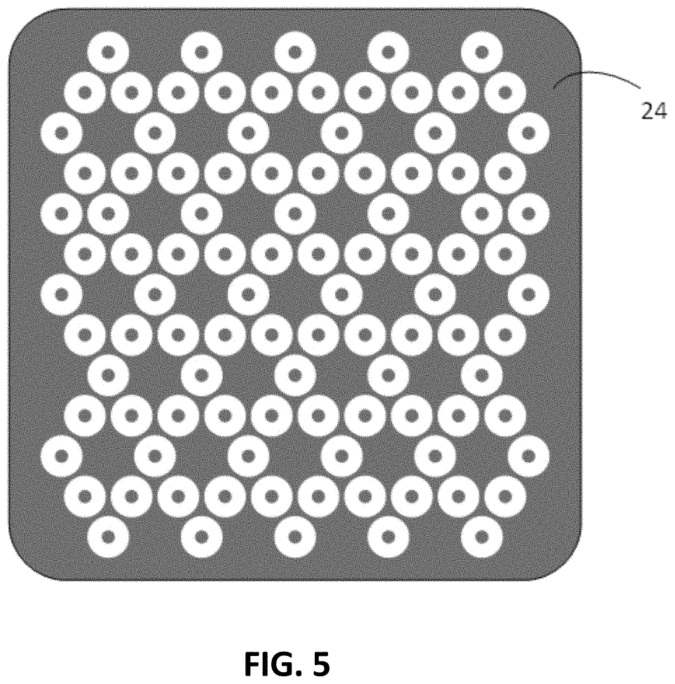

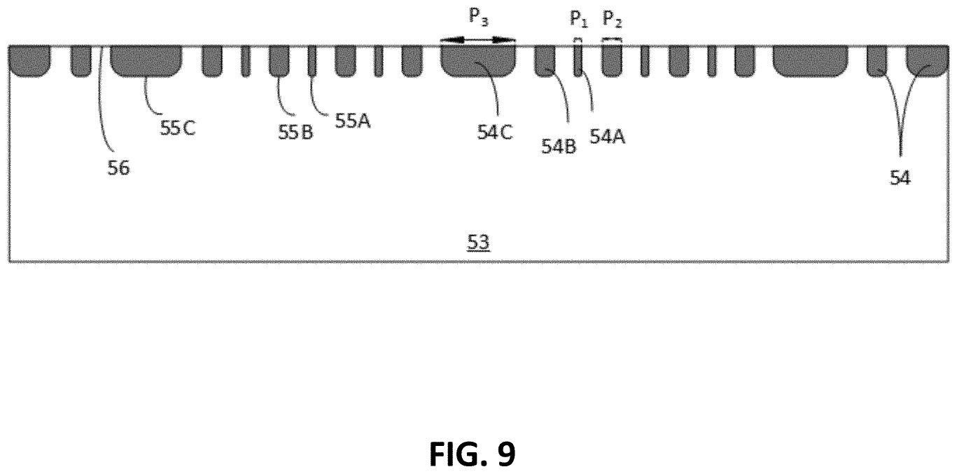

As such, based on the layout design shown in FIG. 2, in a second embodiment, the spacing of P+ regions keeps constant and the circle cell is added as shown in FIG. 5. Here, the second conductivity type region has a wider width (P₃). Because the PN junction with P₃ width (see FIG. 9, structure 55C) has a smaller threshold current I₃ compared to I₂, it can be turned on even earlier, and enhancing the surge current capability of the device.

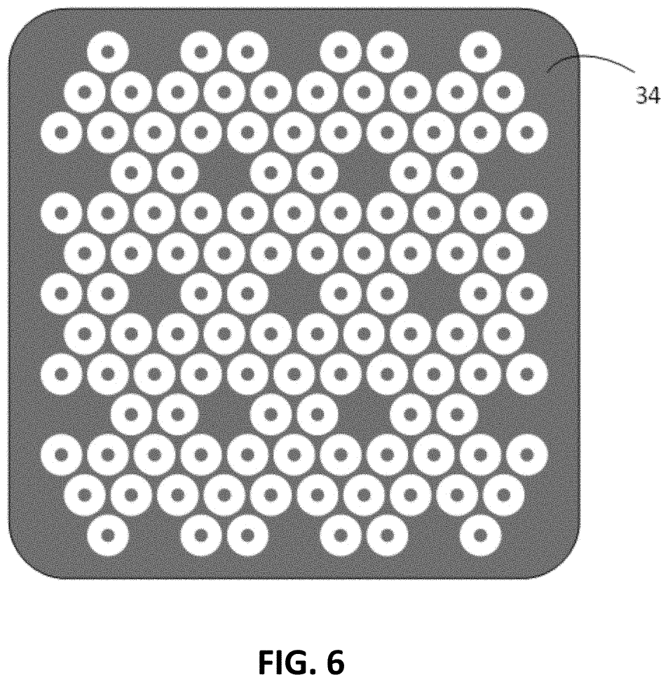

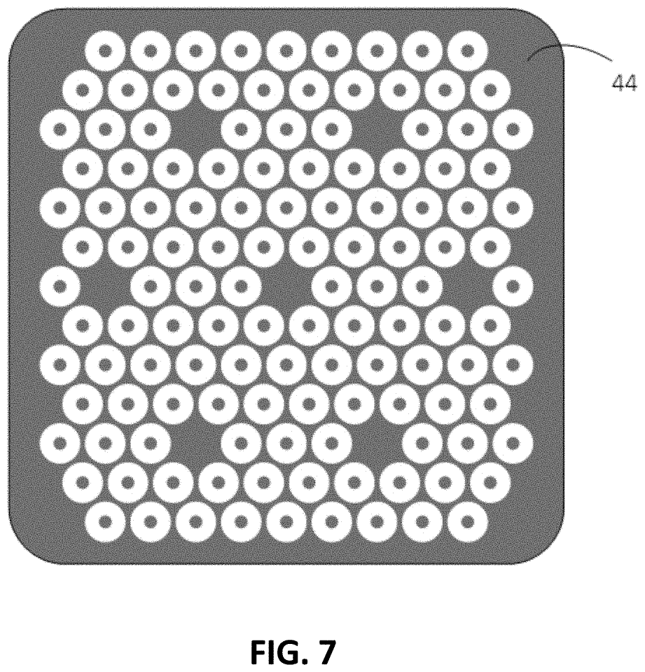

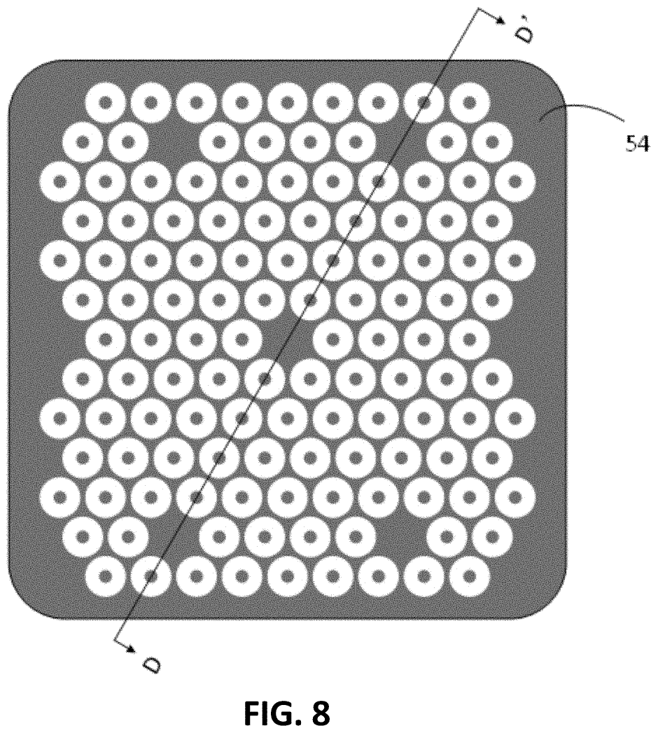

The layout designs of FIGS. 5 to 8 can be formed through different arrangements of the circle cells. As shown in FIGS. 5 to 8, each circle cell in the second embodiment can be surrounded by the n layer(s) of the circle cell in the first embodiment, where n can be 1 to 200.

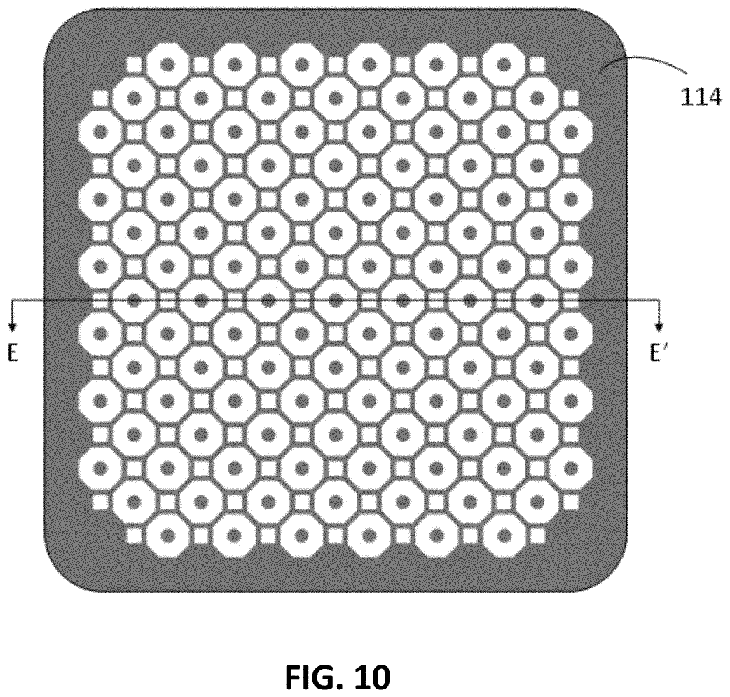

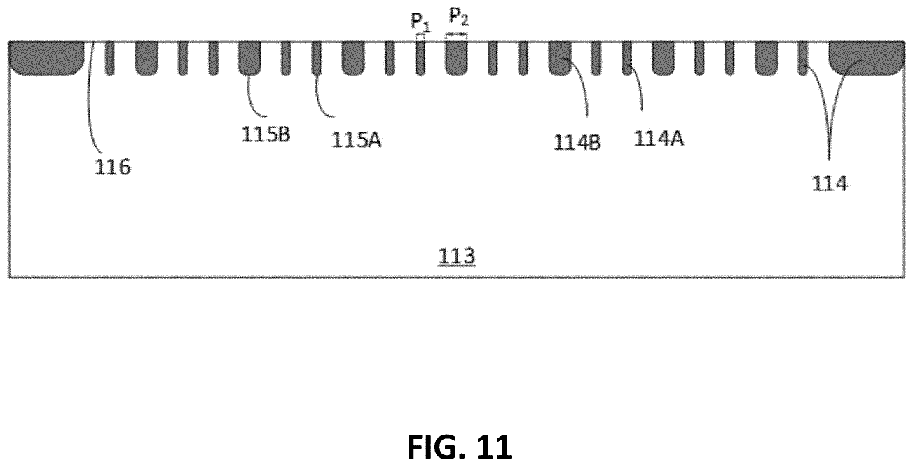

Through calculation, it is found that compared with regular polygons, P+ regions in circle cell design takes too much active area during the arrangement so the Schottky area ratio is only 50.49%. Thus, an octagon cell structure is proposed here for efficient layout design. It is important to note that in order to achieve close-packed arrangement, a square cell is used to fill the gap between the octagonal cells which is shown in FIG. 10, and FIG. 11 is a cross-section view of the MPS diode with the octagonal cells and square cells along EE′ shown in FIG. 10. It is noted that for the layout design in FIG. 10, the width of second conductivity regions as P₁ and P₂ can still be kept, and the Schottky ratio of the device is increased to 52.98%.

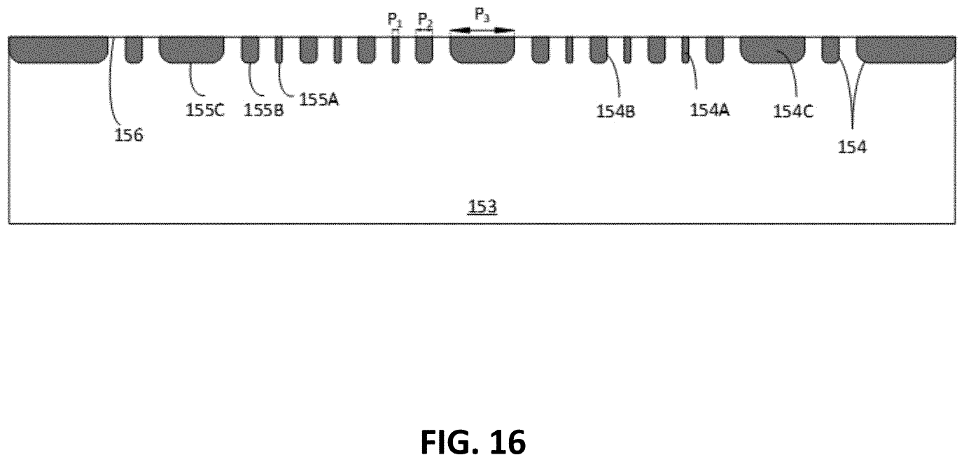

On the basis of the device design shown in FIG. 10, another octagonal cell is added for a third embodiment, where the second conductivity region has a wider width of P₃. The PN junction with P₃ width (see FIG. 16 structure 155C) has a smaller current threshold I₃ than I₂ of the P₂ wide PN junction, which can be turned on at a lower voltage, thus enhancing the surge current capability of the device.

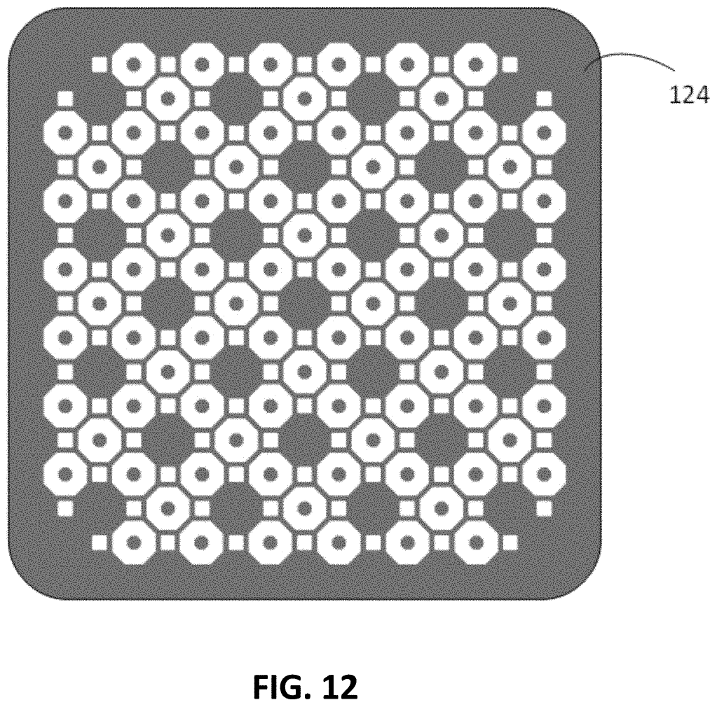

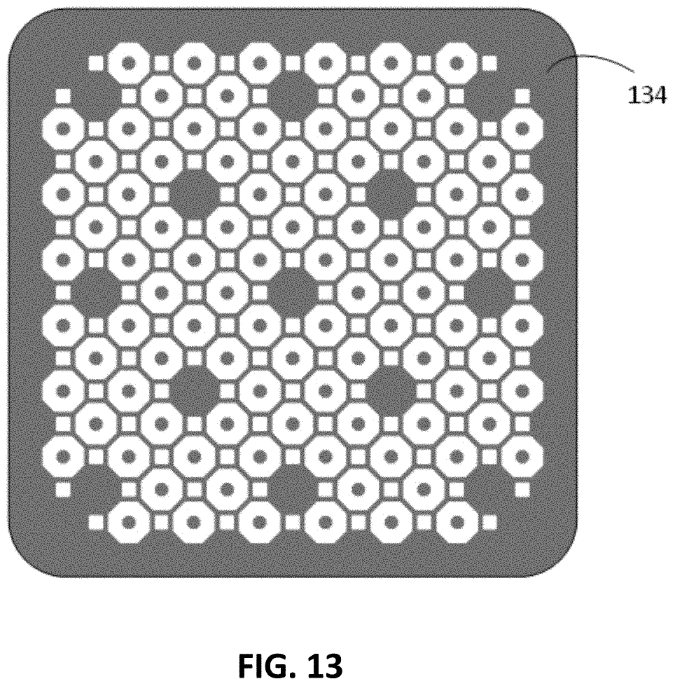

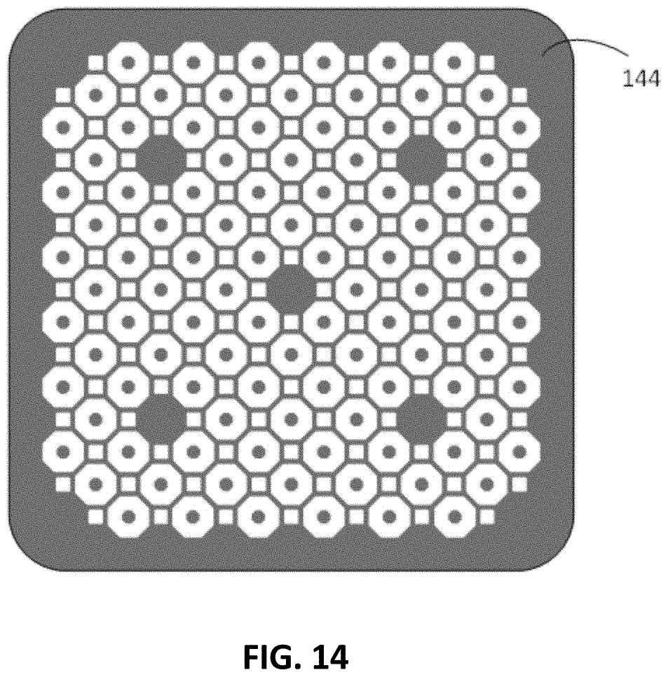

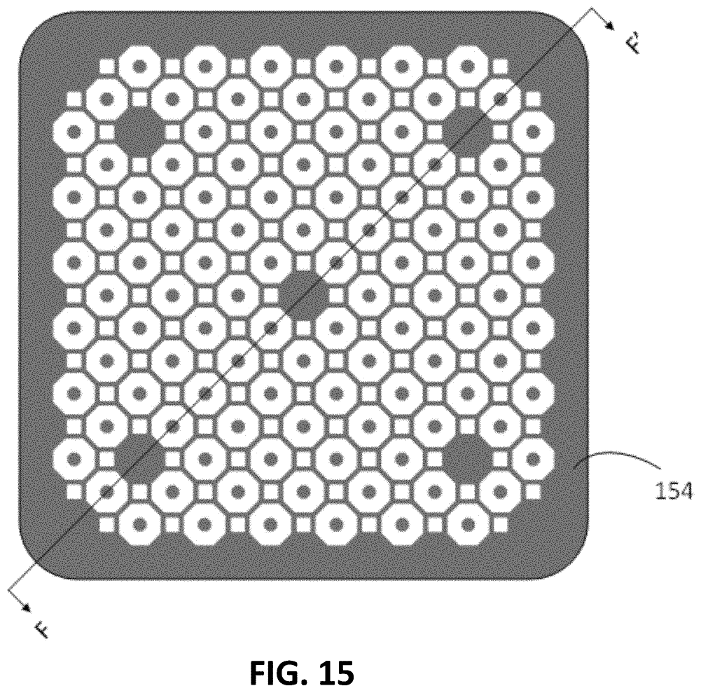

Through different arrangements of the octagonal cells in shown FIGS. 10 and 12, the layout designs shown in FIGS. 13 to 15 can be obtained. Similarly, each octagonal cell in FIG. 12 can be surrounded by n layer(s) of the octagonal cells in FIG. 10, where n can be 1 to 200.

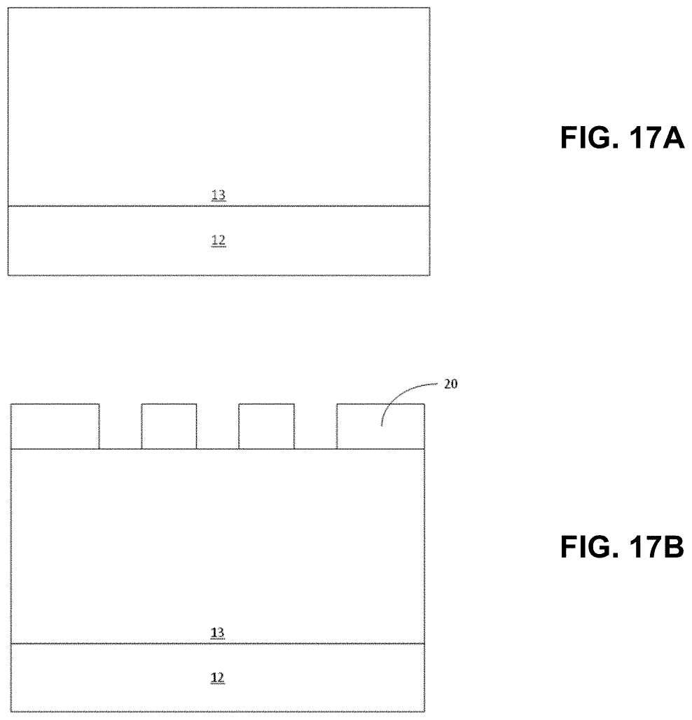

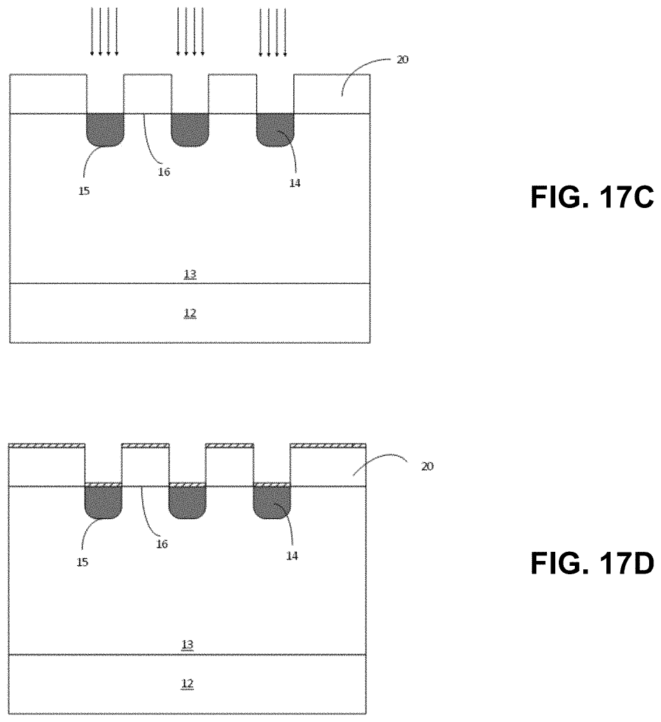

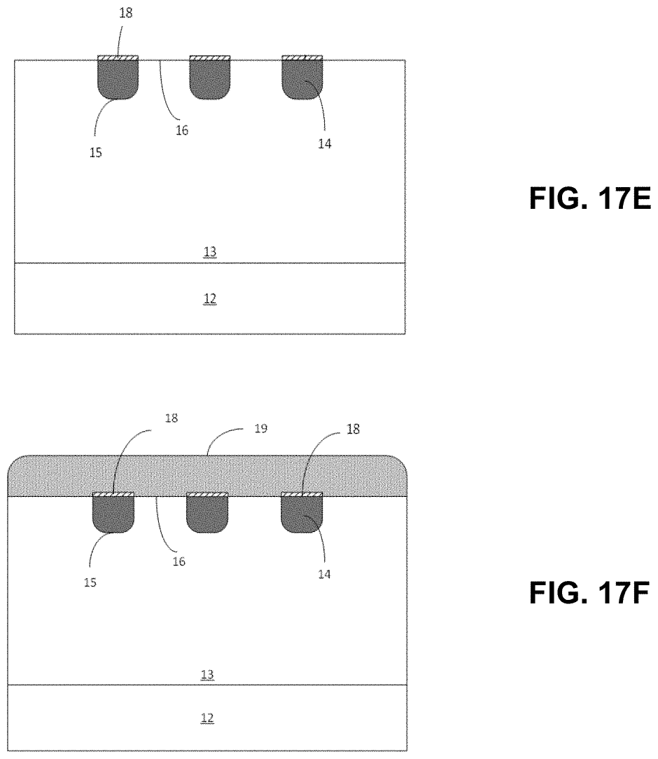

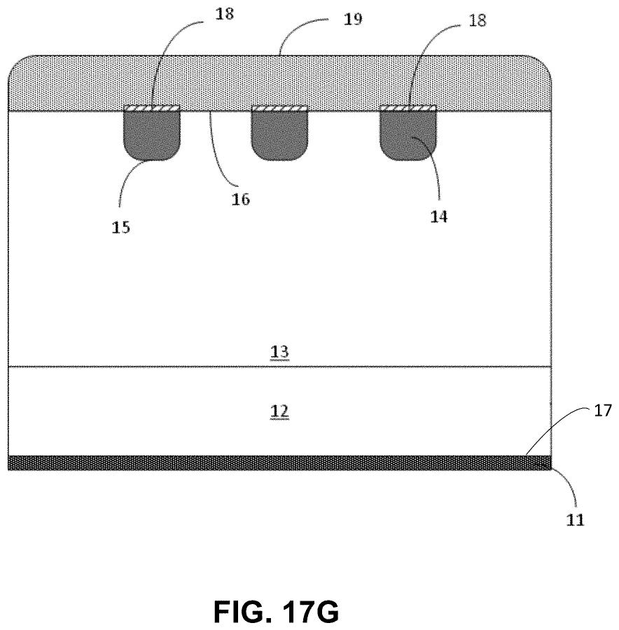

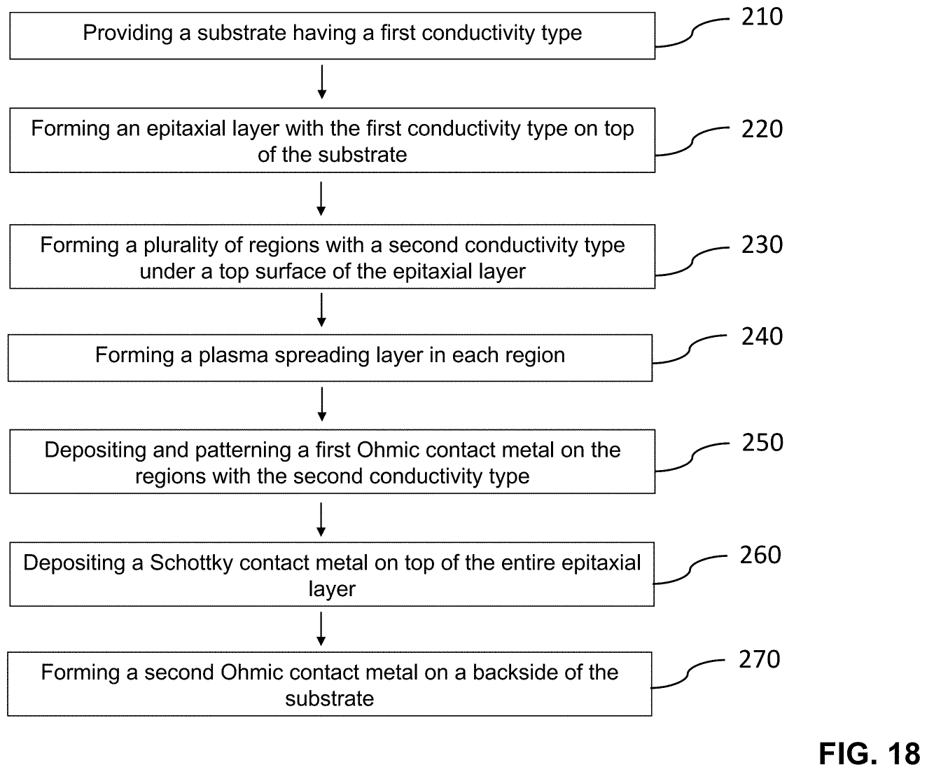

In another aspect, as shown in FIGS. 17A to 17G, and 18, a method for manufacturing a merged PiN Schottky (MPS) diode may include steps of providing a substrate having a first conductivity type 210; forming an epitaxial layer with the first conductivity type 220 on top of the substrate; forming a plurality of regions with a second conductivity type under a top surface of the epitaxial layer 230; forming a plasma spreading layer in each region 240; depositing and patterning an Ohmic contact metal on the regions with the second conductivity type 250; depositing a Schottky contact metal on top of the entire epitaxial layer 260; and forming an Ohmic contact metal on a backside of the substrate 270.

In one embodiment, the epitaxial layer is made of N-type silicon carbide. In another embodiment, the step of forming a plurality of regions with a second conductivity type under a top surface of the epitaxial layer 230 may include steps of depositing and patterning a mask layer 20 on the epitaxial layer 2301, implanting P-type dopant into the epitaxial layer 2302, and removing the mask layer 2303. It is noted that the dopant can be aluminum or boron.

In a further embodiment, the step of depositing and patterning an Ohmic contact metal on the regions 240 may include a step of annealing the Ohmic metal to enable the metal to be in direct contact with the epitaxial layer. In still a further embodiment, the step of depositing a Schottky contact metal on top of the entire epitaxial layer 250 may include a step of conducting a low temperature annealing of the Schottky contact metal.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A semiconductor device comprising:
a substrate having a first conductivity type;
an epitaxial layer having the first conductivity type deposited on one side of the substrate;
a plurality of regions having a second conductivity type formed under a top surface of the epitaxial layer;
a first Ohmic metal patterned and deposited on top of the regions with the second conductivity type;
a Schottky contact metal deposited on top of the entire epitaxial layer to form a Schottky junction; and
a second Ohmic metal deposited on a backside of the substrate,
wherein the regions include one or more wide regions, each having different widths that can be optimized to simultaneously obtain high surge current capability and preserve a low forward voltage drop and reverse leakage current.

2. The semiconductor device of claim 1, wherein the first conductivity type is N-type and the second conductivity type is P-type; and each of the regions is a P+ region.

3. The semiconductor device of claim 1, wherein the semiconductor device is a merged PiN Schottky (MPS) diode.

4. The semiconductor device of claim 2, wherein a PN junction formed between each of the P+ regions and N-type drift regions is turned on when the surge current occurs.

5. The semiconductor device of claim 2, wherein the shape of each P+ region is circle, square, hexagon, octagon, other polygons, or the combination thereof.

6. A method for manufacturing a merged PiN Schottky (MPS) diode comprising steps of:
providing a substrate having a first conductivity type;
forming an epitaxial layer with the first conductivity type on top of the substrate; forming a plurality of regions with a second conductivity type under a top surface of the epitaxial layer;
depositing and patterning a first Ohmic contact metal on the regions with the second conductivity type;
depositing a Schottky contact metal on top of the entire epitaxial layer; and
forming a second Ohmic contact metal on a backside of the substrate,
wherein a junction is formed between each region with second conductivity type and a drift region with first conductivity type, and a threshold potential to turn on the junction is determined by a width of each region.

7. The method for manufacturing a merged PiN Schottky (MPS) diode of claim 6, wherein the epitaxial layer is made of N-type silicon carbide, and the first conductivity type is P-type.

8. The method for manufacturing a merged PiN Schottky (MPS) diode of claim 6, wherein the step of forming a plurality of regions with a second conductivity type under a top surface of the epitaxial layer may include steps of depositing and patterning a mask layer on the epitaxial layer, implanting P-type dopants into the epitaxial layer, and removing the mask layer.
